(19) United States
(12) Patent Application Publication
(10) Pub. No.: US 2026/0123050 A1
(43) Pub. Date: Apr. 30, 2026

(54) ARRAY SUBSTRATE AND DISPLAY PANEL WITH LESS WIRING ERRORS WITH LOW COST, AND METHOD OF PRODUCING THE ARRAY SUBSTRATE

(71) Applicant: Sharp Display Technology Corporation, Kameyama City (JP)

(72) Inventors: Kazuya NAKAJIMA, Kameyama City (JP); Hirokazu FURUKAWA, Kameyama City (JP); Hidefumi KODAKA, Kameyama City (JP); Shigeki UEDA, Kameyama City (JP); Masato ENDOH, Kameyama City (JP); Motohiro OKUYAMA, Kameyama City (JP); Taichi ODAGAMI, Kameyama City (JP); Kenroh YAMAWAKI, Kameyama City (JP)

(21) Appl. No.: 19/003,192

(22) Filed: Dec. 27, 2024

(30) Foreign Application Priority Data
Feb. 16, 2024 (JP) 2024-022092

(51) Int. Cl. H10D 86/40; G02F 1/1362; G02F 1/1368; H10D 86/01; H10D 86/60

(52) U.S. Cl. CPC H10D 86/443; G02F 1/136204; G02F 1/136286; G02F 1/1368; H10D 86/0231; H10D 86/60

(57) ABSTRACT

In a non-display area, an array substrate includes first line sections that are portions of a first conductive film and extend in an extending direction along an outer peripheral edge portion of a display area and are disposed with a first space in the extending direction, and second line sections that are portions of a second conductive film disposed on the first conductive film via a first insulating film. The second line sections are disposed to overlap end portions of the first line sections, respectively, and disposed with a second space that is smaller than the first space. The second line sections are connected to the first line sections, respectively via contact portions that are through the first insulating film. Each of the second line sections has a planar size that is smaller than a planar size of each of the first line sections.

### CROSS REFERENCE TO RELATED APPLICATION

This application claims priority from Japanese Patent Application No. 2024-022092 filed on Feb. 16, 2024. The entire contents of the priority application are incorporated herein by reference.

### TECHNICAL FIELD

The present technology described herein relates to an array substrate and a display device that suppress wiring errors with low cost and a method of producing such an array substrate.

### BACKGROUND

If electrostatic discharge (ESD) occurs in a photomask that is used in the photolithography during a process of producing a display panel, the planar pattern of the photomask may be deformed. With the photomask being deformed, wiring errors such as short-circuit may be caused in the lines formed with using the deformed photomask. The technology of reducing occurrence of ESD in a photomask has been known.

One of examples of such photomasks includes a light blocking portion that includes a light blocking layer mainly made of chromium and an antistatic layer that is formed at least in a transmissive area, which includes no light blocking portion, and includes chromium. With such a configuration, electrostatic breakdown caused by ESD in the photomask may be prevented.

However, such a photomask includes the antistatic layer and this increases a cost. Furthermore, in the exposing with using the photomask, the production process needs to be monitored such that the exposure transmittance is not decreased. This lowers operation efficiency and increases operation cost.

### SUMMARY

The technology described herein was made in view of the above circumstances. An object is to decrease wiring errors with low cost.
(1) An array substrate according to the technology described herein includes a display area and a non-display area that surrounds the display area. In the non-display area, the array substrate includes first line sections that are portions of a first conductive film and extend in an extending direction along an outer peripheral edge portion of the display area and are disposed with a first space between the first line sections in the extending direction, and second line sections that are portions of a second conductive film disposed on the first conductive film via a first insulating film. The second line sections are disposed to overlap end portions of the first line sections, respectively, and disposed with a second space between the second line sections, the second space being smaller than the first space. The second line sections are connected to the first line sections, respectively via contact portions that are through the first insulating film. Each of the second line sections has a planar size that is smaller than a planar size of each of the first line sections.
(2) In the array substrate, in addition to (1), the second line sections may have end portions that are opposite the second space and have a tapered shape.
(3) In the array substrate, in addition to (1) or (2), the end portions of the first line sections may have a non-tapered shape.
(4) The array substrate may further include, in addition to any one of (1) to (3), TFTs arranged in a matrix in the display area. The TFTs may include gate electrodes that are portions of the first conductive film and source electrodes that are portions of the second conductive film.
(5) A display panel according to the technology described herein includes the array substrate according to any one of (1) to (4), an opposed substrate opposed to the array substrate with having an inner space therebetween, and a liquid crystal layer disposed in the inner space.
(6) A display panel according to the technology described herein includes the array substrate according to any one of (1) to (4), light emission components disposed on the array substrate, and a sealing layer disposed to cover the light emission components.
(7) A method of producing an array substrate according to the technology described herein includes a display area where TFTs are arranged in a matrix and a non-display area surrounding the display area and the method includes forming a first conductive film on an insulating substrate, etching the first conductive film with patterning via a first photomask and forming first line sections that extend in an extending direction in the non-display area along an outer peripheral edge of the display area and are disposed with a first space in the extending direction, forming a first insulating film on the first line sections, etching the first insulating film with patterning via a second photomask and forming contact holes in the first insulating film, forming a second conductive film on the first insulating film that is patterned and connecting the second conductive film and the first line sections with the second conductive film being disposed in the contact holes, and etching the second conductive film, which is connected to the first line sections, with patterning via a third photomask that has a light blocking portion having a smaller planar size than the first photomask and forming second line sections so as to overlap end portions of the first line sections and to be arranged with a second space that is smaller than the first space.
(8) In the method of producing an array substrate, in addition to (7), the second line sections may have end portions that are opposite the second space and have a tapered shape.
(9) In the method of producing an array substrate, in addition to (7) or (8), the end portions of the first line sections may have a non-tapered shape.
(10) In the method of producing an array substrate, in addition to any one of (7) to (9), the first conductive film may be a gate metal film including portions that are configured as gate electrodes of the TFTs, and the second conductive film may be a source metal film including portions that are configured as source electrodes of the TFTs.

According to the technology described herein, wiring errors can be decreased with low cost.

### BRIEF DESCRIPTION OF THE DRAWINGS

FIG. 1 is a plan view of a liquid crystal panel according to one embodiment.

FIG. 2 is a cross-sectional view of the liquid crystal panel taken along line II-II in FIG. 1.

FIG. 3 is a circuit diagram illustrating a pixel arrangement of an array substrate in a display area.

FIG. 4 is a plan view illustrating a layout pattern of a framed portion IV in FIG. 1.

FIG. 5 is a cross-sectional view taken along line V-V in FIG. 4.

FIG. 6A is a cross-sectional view of a substrate that is in one of steps of a producing process of the array substrate in FIG. 5.

FIG. 6B is a cross-sectional view of a substrate that is in one of the steps of the producing process of the array substrate after FIG. 6A.

FIG. 6C is a cross-sectional view of a substrate that is in one of the steps of the producing process of the array substrate after FIG. 6B.

FIG. 6D is a cross-sectional view of a substrate that is in one of the steps of the producing process of the array substrate after FIG. 6C.

FIG. 6E is a cross-sectional view of a substrate that is in one of the steps of the producing process of the array substrate after FIG. 6D.

FIG. 6F is a cross-sectional view of a substrate that is in one of the steps of the producing process of the array substrate after FIG. 6E.

FIG. 6G is a cross-sectional view of a substrate that is in one of the steps of the producing process of the array substrate after FIG. 6F.

FIG. 6H is a cross-sectional view of a substrate that is in one of the steps of the producing process of the array substrate after FIG. 6G.

FIG. 6I is a cross-sectional view of a substrate that is in one of the steps of the producing process of the array substrate after FIG. 6H.

FIG. 7 is a plan view illustrating a layout pattern of Comparative Example.

FIG. 8 is an exploded perspective view illustrating a configuration of an organic EL panel of other embodiment.

### DETAILED DESCRIPTION

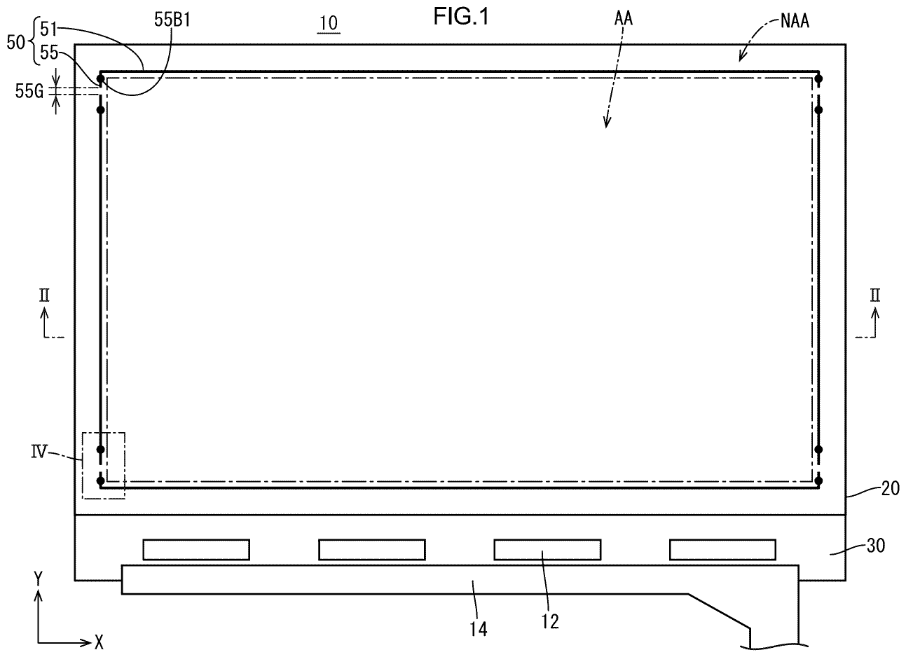

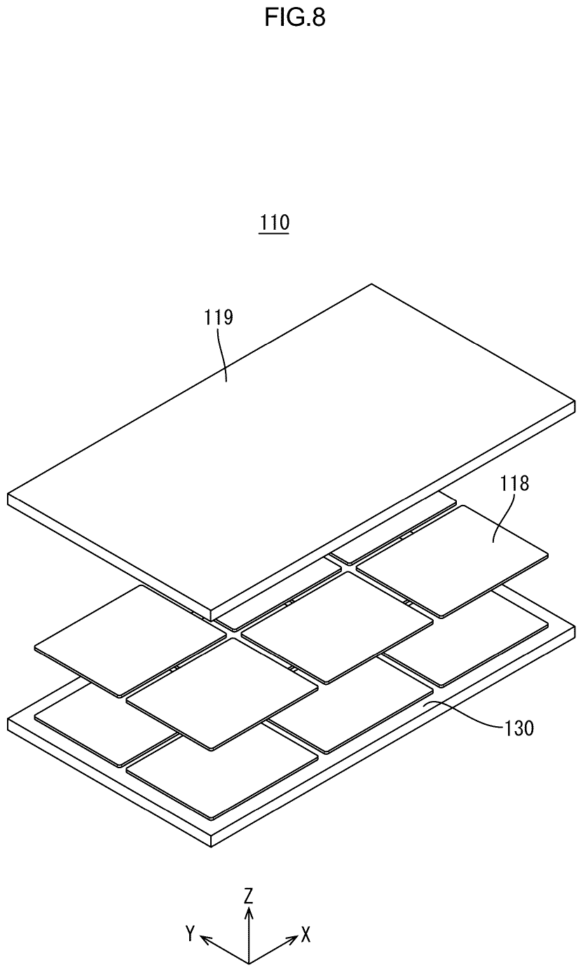

A liquid crystal panel 10 (one example of a display panel) according to one embodiment will be described with reference to FIGS. 1 to 6I. Other types of display panels (such as an organic EL panel 110 illustrated in FIG. 8) may be used. X-axes, Y-axes, and Z-axes may be present in the drawings. The axes in each drawing correspond to the respective axes in other drawings. An upper side and a lower side in each cross-sectional view correspond to a front side and a back side, respectively.

As illustrated in FIG. 1, an inner surface of the liquid crystal panel 10 is divided into a display area AA (an active area) and a non-display area NAA (a non-active area). The display area AA is a middle section of the inner surface and images are displayed on the display area AA. The non-display area NAA is an outer section in a frame plan view shape surrounding the display area AA. In FIG. 1, the outline of the display area AA is illustrated with a chain line and an area outside the chain line is the non-display area NAA. The planar shape of the liquid crystal panel 10 is not limited to a special shape. In this embodiment, the liquid crystal panel 10 has a laterally long rectangular plan view shape as a whole. A long-side direction corresponds to the X-axis direction, a short-side direction corresponds to the Y-axis direction, and a thickness direction corresponds to the Z-axis direction.

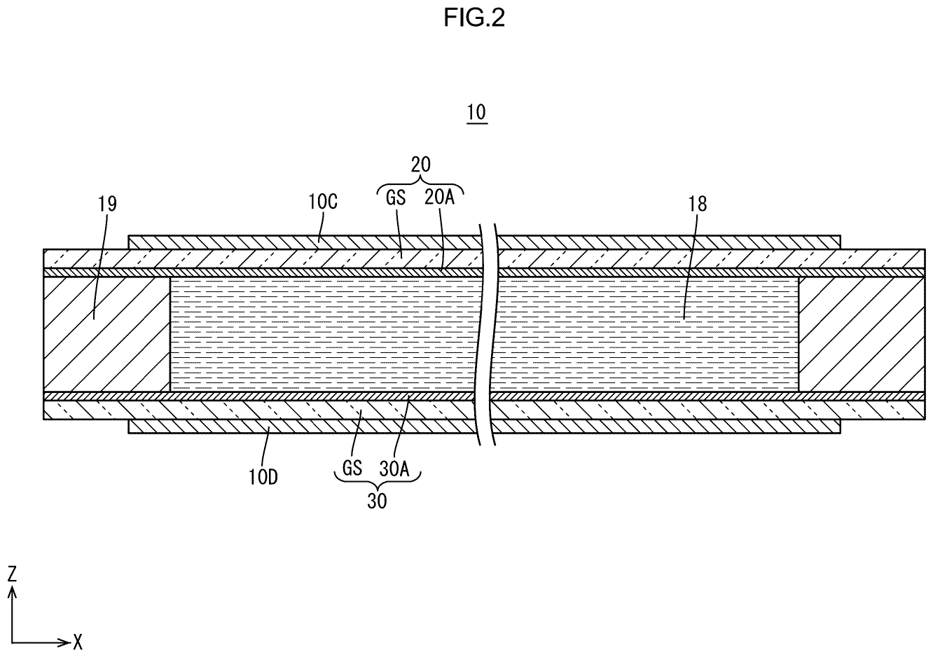

As illustrated in FIG. 2, the liquid crystal panel 10 includes a pair of substrates 20, 30 that are bonded to each other. At least a liquid crystal layer 18 and a sealing portion 19 for sealing the liquid crystal layer 18 are disposed between the substrates 20 and 30. The liquid crystal layer 18 includes liquid crystal molecules having optical characteristics that vary according to application of electric field. The sealing portion 19 is formed in a rectangular frame plan view shape as a whole and surrounds the liquid crystal layer 18 in the non-display area NAA. Polarizing plates 10C, 10D are attached to outer surfaces of the substrates 20 and 30, respectively.

One of the substrates 20, 30 on the front side (a display surface side) is an opposed substrate 20 (a color filter substrate) and another one on the back side is an array substrate 30 (an active matrix substrate, a TFT substrate). The opposed substrate 20 and the array substrate 30 include glass substrates GS (an example of an insulating substrate) that are almost transparent and have good light transmissive properties and various kinds of films 20A, 30A that are formed in layers on an inner surface side the glass substrates GS. A backlight unit that supplies light to the liquid crystal panel 10 is disposed behind the liquid crystal panel 10 (opposite the array substrate 30) and the backlight unit and the liquid crystal panel 10 are configured as a liquid crystal display device.

As illustrated in FIG. 1, the array substrate 30 has a long-side dimension that is substantially same as a long-side dimension of the opposed substrate 20 and has a short-side dimension that is longer than a short-side dimension of the opposed substrate 20. Therefore, with the array substrate 30 and the opposed substrate 20 being bonded such that one of the long sides of the opposed substrate 20 and one of the long sides of the array substrate 30 are aligned with each other, the array substrate 30 includes an uncovered portion that does not overlap the opposed substrate 20. Drivers 12 for driving the liquid crystal panel 10 are mounted on the non-overlapping portion of the array substrate 30 through the chip-on-glass (COG) technology. The drivers 12 are connected to a flexible substrate 14. A first end of the flexible substrate 14 is connected to the non-display area NAA of the liquid crystal panel 10 and a second end of the flexible substrate 14 is connected to a control board. Various kinds of signals supplied from the control board are transmitted to the liquid crystal panel 10 via the flexible substrate 14.

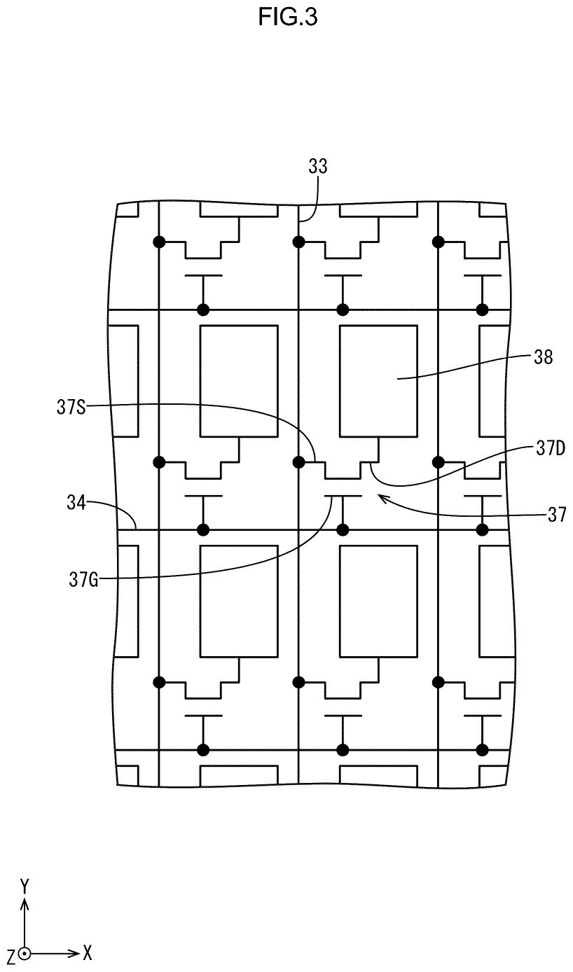

As illustrated in FIG. 3, source lines 33 (data lines, signal lines) and gate lines 34 (scan lines) are arranged in a grid in the display area AA of the array substrate 30. The source lines 33 extend along the Y-axis direction and the gate lines 34 extend along the X-axis direction that is perpendicular to the direction in which the source lines 33 extend. A thin film transistor 37 (TFT), which is a switching component, and a pixel electrode 38 are disposed in each of sections surrounded by the source lines 33 and the gate lines 34. The TFTs 37 and the pixel electrodes 38 are arranged in a matrix in an entire area of the display area AA.

A common electrode supplied with a reference potential is disposed in the display area AA of the array substrate 30. The common electrode may be included in the opposed substrate 20. With the TFT 37 receiving signals from the source line 33 and the gate line 34, the pixel electrode 38 connected to the TFT 37 is charged and a potential difference between the pixel electrode 38 and the common electrode changes. According to the potential difference, the electric field applied to the liquid crystal layer 18 is controlled such that the orientations of the liquid crystal molecules are appropriately switched and the liquid crystal panel 10 is driven.

The source lines 33 are connected to the driver 12 via extension lines. The source lines 33 are supplied with data signals (image signals) from a source driver circuit in the driver 12. The gate lines 34 are connected to a GDM (gate driver monolithic circuit) section that is monolithically fabricated in the non-display area NAA. The gate lines 34 are supplied with scan signals from the GDM section. The GDM section is connected to the flexible substrate 14 via an extension line and supplied with signals from the control board via the flexible substrate 14.

As illustrated in FIG. 1, auxiliary lines 50 are disposed in the non-display area NAA of the array substrate 30. ESD is intentionally caused by the auxiliary line 50 in the non-display area NAA such that ESD is not caused by static electricity occurring outside the liquid crystal panel 10. Namely, the auxiliary line functions as a lighting rod.

The auxiliary lines 50 extend in the non-display area NAA and along an outer peripheral edge of the display area AA. The position relation of the auxiliary lines 50 and other components such as the GDM section, common electrode lines for supplying a reference potential signal to the common electrode, and a test line for performing an operation test of the liquid crystal panel is not particularly limited as long as the auxiliary lines 50 extend along the outer peripheral edge of the display area AA.

The auxiliary lines 50 of this embodiment are formed in a rectangular frame shape that surrounds the entire outer peripheral edge of the display area AA. However, the auxiliary lines 50 may not be disposed to extend along the entire periphery of the display area AA as long as the auxiliary lines 50 extend along the outer peripheral edge of the display area AA. For example, the auxiliary lines 50 may be formed in a U-shape and surround three sides of the rectangular frame-shaped outer peripheral edge of the display area AA or may be formed in an L-shape and surround two sides of the rectangular frame-shaped outer peripheral edge of the display area AA.

In this embodiment, four auxiliary lines 50 are disposed with spaces (a second space 55G between second auxiliary line sections 55) with respect to an extending direction in which the auxiliary line 50 extends. ESD is caused between end portions of the auxiliary lines 50 that are opposite each other via the space (the second space 55G). Specifically, ESD is caused between first end portions 55A (extending end portions) of the second auxiliary line sections 55. In this embodiment, four spaces, each of which is between the auxiliary lines 50, are at four corners of the rectangular display area AA, respectively. However, the spaces may be on portions other than the corners and the number of spaces may not be four.

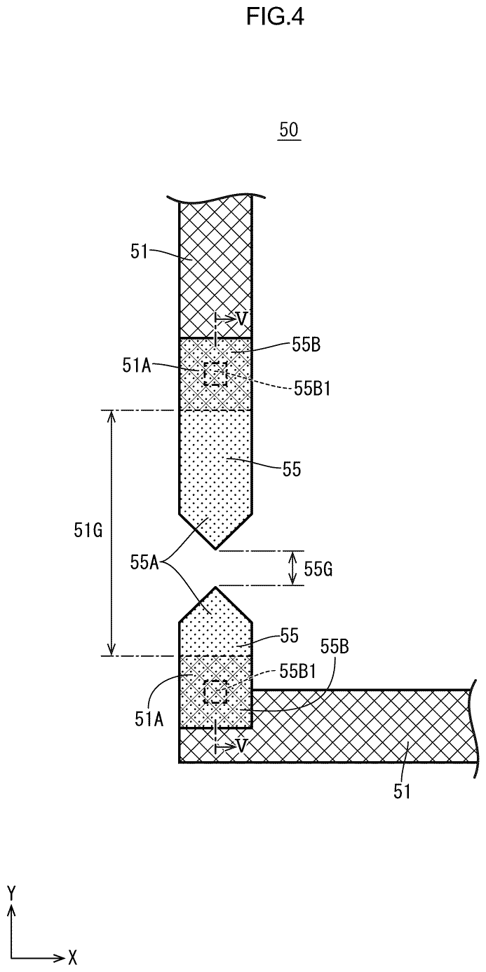

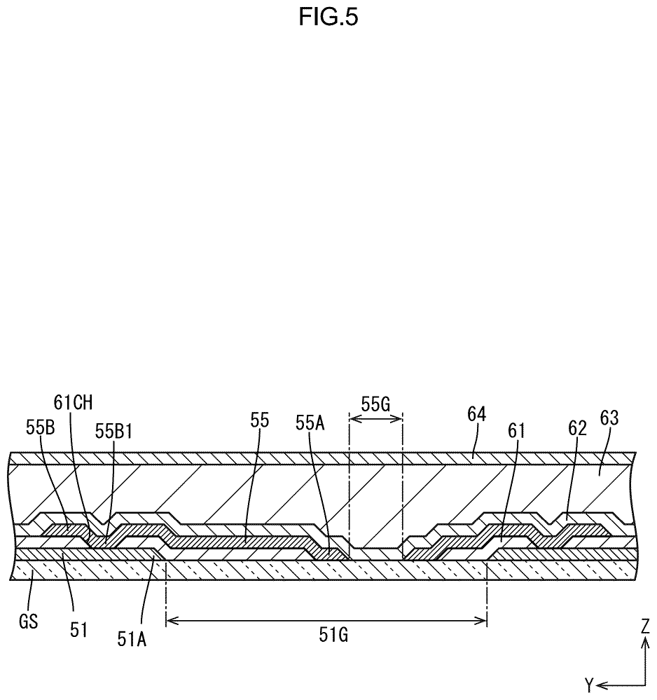

The auxiliary line 50 includes a first auxiliary line section 51 (one example of a first line section) and the second auxiliary line section 55 (one example of a second line section). The first auxiliary line section 51 corresponds to a most part of the auxiliary line 50 and extends along the outer peripheral edge of the display area AA. As illustrated in FIGS. 4 and 5, the two adjacent first auxiliary line sections 51 are disposed with having a first space 51G therebetween with respect to the extending direction in which the auxiliary line 50 extends. The number of the first auxiliary line sections 51 is same as the number of the auxiliary lines 50. Namely, four first auxiliary line sections 51 are disposed. The first space 51G is greater than the space between the auxiliary lines 50, which is the second space 55G between the second auxiliary line sections 55. An end portion 51A of the first auxiliary line section 51 preferably has a non-tapered shape so as not to function as a protrusion that may cause discharge.

The second auxiliary line section 55 is disposed to overlap the end portion 51A of the first auxiliary line section 51 in a plan view. A planar size of the second auxiliary line section 55 is much smaller than that of the first auxiliary line section 51. The second auxiliary line section 55 is disposed only near the end portion 51A of the first auxiliary line section 51. More in detail, the second auxiliary line section 55 is formed to extend from the end portion 51A of the first auxiliary line section 51 in the extending direction in which the first auxiliary line section 51 extends. The second auxiliary line section 55 is configured as an extending portion of the first auxiliary line section 51 with a multi-layered structure.

The second auxiliary line section 55 of this embodiment is disposed for each of the end portions 51A of the first auxiliary line section 51. Namely, two second auxiliary line sections 55 are disposed for each of the four first auxiliary line sections 51. Therefore, eight second auxiliary line sections 55 are disposed corresponding to eight end portions 51A. The second auxiliary line section 55 is disposed on each end portion 51A of the first auxiliary line sections 51. The first end portions 55A (the extending end portion) of the second auxiliary line sections 55 that are disposed on the two adjacent first auxiliary line sections 51 are opposite with the second space 55G therebetween.

Therefore, the second auxiliary line sections 55 are spaced from each other with the second space 55G that is smaller than the first space 51G. The shape of the first end portions 55A (an end portion opposite the second space 55G) of the second auxiliary line section 55 is not particularly limited to a specific shape but preferably is a tapered shape such that the first end portions 55A function as protrusions that cause discharge. As illustrated in FIG. 5, a second end portion 55B of the second auxiliary line section 55 that is an opposite end portion from the first end portion 55A overlaps the end portion 51A of the first auxiliary line section 51 via a first insulating film 61. The second end portion 55B of the second auxiliary line section 55 is connected to the end portion 51A of the first auxiliary line section 51 via a contact portion 55B1 that is through the first insulating film 61.

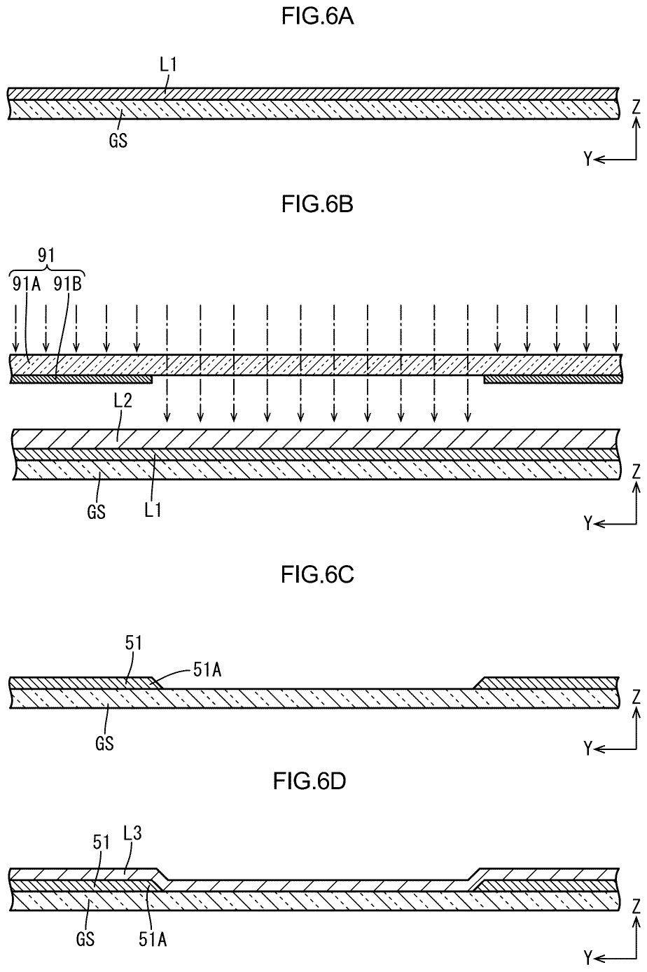

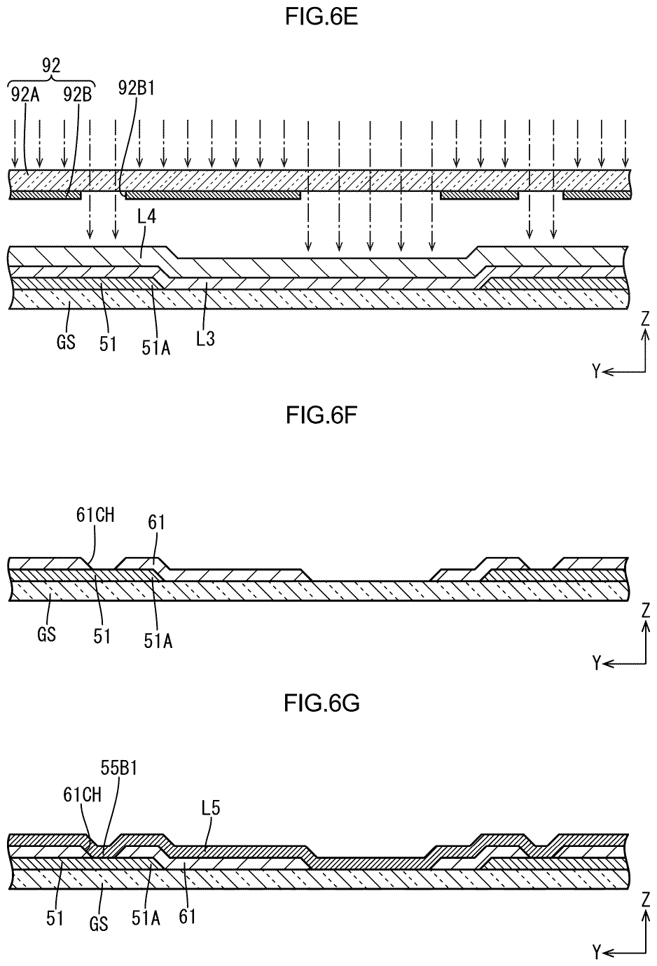

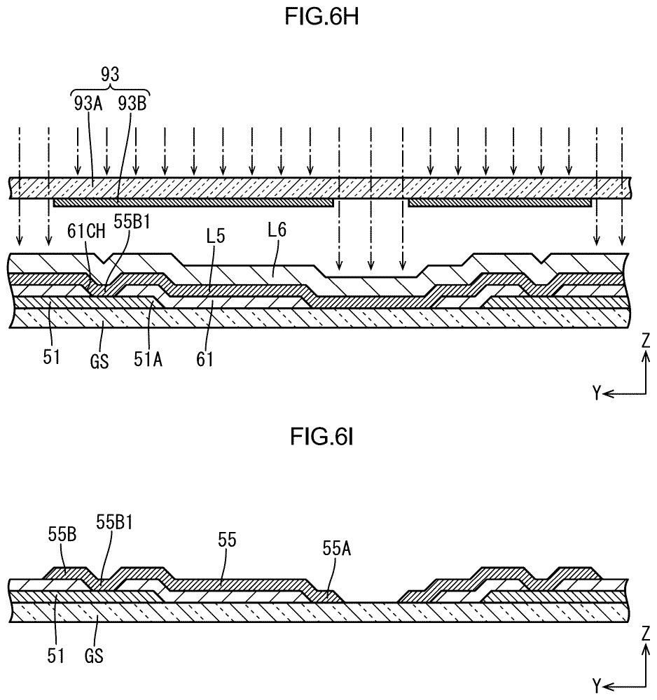

A method of producing the array substrate 30 will be described with reference to FIGS. 6A to 6I. Particularly, a method of producing a portion of the array substrate 30 including the auxiliary lines 50 will be described. First, as illustrated in FIG. 6A, a gate metal film L1 (one example of a first conductive film) is formed on a glass substrate GS with plasma chemical vapor deposition (CVD) or sputtering. The gate metal film L1 includes portions that are configured as the first auxiliary line sections 51, the gate lines 34, and gate electrodes 37G of the TFTs 37. Each of the gate metal film L1 and a source metal film L5 (one example of a second conductive film) is a single-layer film made of metal such as copper (Cu) or alloy, or a multilayer film made of different kinds of metals.

Next, a first resist film L2 is formed on the gate metal film L1. Known photoresist material, which is commonly used in photolithography, is used for the first resist film L2, a second resist film L4, and a third resist film L6 as appropriate. As illustrated in FIG. 6B, the first resist film L2 that is covered with a first photomask 91 is exposed with light by an exposure device. The first photomask 91, a second photomask 92, and a third photomask 93 have a general configuration that is used in photolithography and include transparent substrates 91A, 92A, 93A and light blocking portions 91B, 92B, 93B, respectively. The light blocking portions 91B, 92B, 93B are made of light blocking material such as chromium and disposed on the transparent substrates 91A, 92A, 93A, respectively.

Next, the exposed first resist film L2 is developed to form a first resist pattern. The gate metal film L1 is etched with using the first resist pattern as a mask. Thus, the first auxiliary line sections 51 are formed and the resist pattern is removed as illustrated in FIG. 6C. After forming the first auxiliary line sections 51, the gate insulating film L3 is formed in a layer above a layer including the first auxiliary line sections 51 as illustrated in FIG. 6D. The gate insulating film L3 includes portions that are configured as the first insulating film 61 and a gate insulating film of the TFTs 37 (an insulating film between the gate electrode 37G and a semiconductor film). The gate insulating film L3, a second insulating film 62, and a third insulating film 64 are made of transparent inorganic insulating material and each of the films is a single-layer film or a multilayer film including SiOₓ (silicon oxide), SiON (silicon oxynitride), and SiNₓ (silicon nitride).

Next, the second resist film L4 is disposed with coating on the gate insulating film L3. As illustrated in FIG. 6E, the second resist film L4 is covered with the second photomask 92 and exposed with light by an exposure device. The exposed second resist film L4 is developed and a second resist pattern is formed. As illustrated in FIG. 6F, the gate metal film L3 is etched with using the second resist pattern as a mask. Thus, the first insulating film 61 is formed and the second resist pattern is removed as illustrated in FIG. 6F. The second photomask 92 includes a transmissive portion 92B1 for forming a contact hole 61CH in the first insulating film 61.

After forming the first insulating film 61, the source metal film L5 is formed in a layer above the layer including the first insulating film 61 as illustrated in FIG. 6G. The source metal film L5 includes portions that are configured as the second auxiliary line sections 55, the source lines 33, and source electrodes 37S and drain electrodes 37D of the TFTs 37. Next, the third resist film L6 is disposed with coating on the source metal film L5. As illustrated in FIG. 6H, the third resist film L6 is covered with the third photomask 93 and exposed with light by an exposure device. The exposed third resist film L6 is developed and a third resist pattern is formed. As illustrated in FIG. 6I, the source metal film L5 is etched with using the third resist pattern as a mask. Thus, the second auxiliary line sections 55 are formed and the third resist pattern is removed as illustrated in FIG. 6I. After forming the second auxiliary line sections 55, the second insulating film 62, a planarization film 63, and the third insulating film 64 are formed sequentially with photolithography. Accordingly, the array substrate 30 illustrated in FIG. 5 is obtained. The planarization film 63 is made of transparent organic insulating material such as acrylic resin (PMMA) and polyimide resin and normally has a film thickness greater than that of other insulation films.

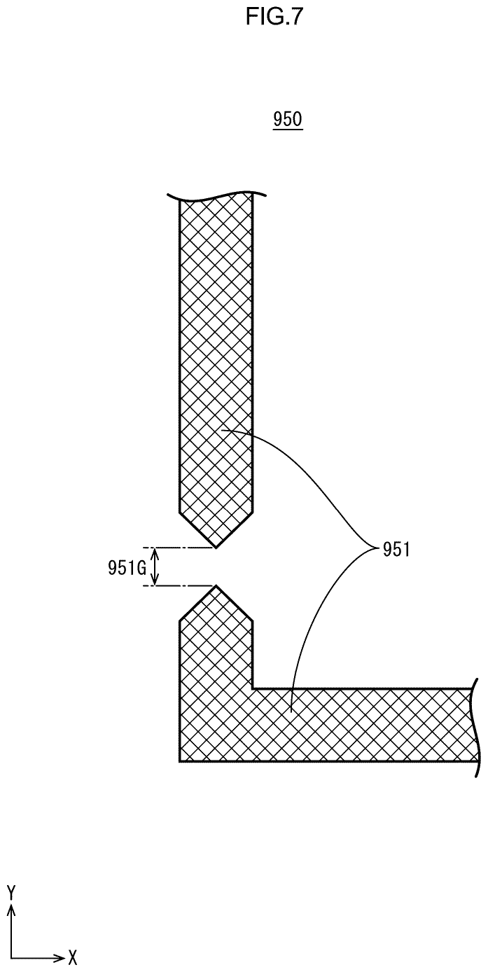

In the producing process with photolithography, the light blocking portion of the photomask may be charged and ESD may be caused. Particularly, the first photomask 91 for forming the first auxiliary line sections 51 has a large planar size and therefore, the amount of electric charge of the first photomask 91 is large. With an auxiliary line 950 of comparative example being formed with one layer as illustrated in FIG. 7 (the auxiliary line 950 includes only a first auxiliary line section 951 of the gate metal film L1), ESD is likely to be caused between end portions of light blocking portions of a first photomask used for forming the auxiliary lines 950. If ESD is caused, the planar pattern of the first photomask is deformed and errors such as short-circuit may be caused by the lines that are formed with using the deformed first photomask.

With a first space 951G between the first auxiliary line sections 951 being increased, occurrence of ESD in the first photomask is suppressed and also ESD is less likely to be caused between the first auxiliary line sections 951. As a result, the auxiliary lines 950 including the first auxiliary line sections 951 may not function as the portion that causes ESD.

In this respect, the auxiliary line 50 of this embodiment has a two-layered structure including the first auxiliary line section 51 and the second auxiliary line section 55. More specifically, the second auxiliary line section 55 is formed to overlap the end portion 51A of the first auxiliary line section 51. Accordingly, the portion between the first end portions 55A of the second auxiliary line sections 55 functions as the portion causing ESD. The space (the second space 55G) between the first end portions 55A of the second auxiliary line sections 55 is smaller than the first space between the first auxiliary line sections 51. With such a configuration, ESD is likely to be caused between the first end portions 55A of the second auxiliary line sections 55.

The second auxiliary line section 55 is disposed to overlap the end portion 51A of the first auxiliary line section 51 in a plan view. With the planar size of the second auxiliary line section 55 being much smaller than that of the first auxiliary line section 51, the planar size of the light blocking portion 93B of the third photomask 93 used for forming the second auxiliary line sections 55 in the producing process is also small. Accordingly, the amount of electric charge of the light blocking portions 93B of the third photomask 93 is small. As a result, unexpected ESD is less likely to be caused between the light blocking portions 93B of the third photomask 93.

According to the auxiliary lines 50 of this embodiment, the photomask does not need to include the antistatic layer unlike the prior art and wiring errors caused due to ESD occurring in the photomask can be reduced with low cost. With the second auxiliary line sections 55 being included in the same layer as the layer including the source lines 33 (the source metal film L2), the array substrate 30 does no need to include an additional conductive film for forming the second auxiliary line sections 55. This surely suppresses increase of cost.

The first space 51G between the first auxiliary line sections 51 has a distance that does not cause ESD. The distance of the first space 51G is determined by the planar size of the first auxiliary line section 51 (the amount of electric charge of the first auxiliary line section 51). With a clearance distance in the air being generally 1 kV/mm, the first space 51G is preferably 10 μm or more.

The second space 55G between the second auxiliary line sections 55 has a distance that can effectively cause ESD. The distance of the second space 55G is a smallest value (the minimum limit value defined by the exposure resolution of the resist film) of the distance between the planar patterns formed with photolithography and is 5 μm or less, for example.

### Other Embodiments

The technology described herein is not limited to the embodiments described above and illustrated by the drawings. For example, the following embodiments will be included in the technical scope of the present technology.
(1) The layered order of the various kinds of thin films of the array substrate 30 may be altered. For example, the gate metal film L1 may be disposed in a layer upper than the layer including the source metal film L2. The first auxiliary line sections 51 may be portions of the source metal film L2 and the second auxiliary line sections 55 may be portions of the gate metal film L1.
(2) The present technology may be applied to different types of display panels such as organic electro luminescence display panels. As illustrated in FIG. 8, the organic EL panel 110 at least includes an array substrate 130, organic light emission layers 118 (light emission components), and a sealing member layer 119 that is disposed to cover the light emission layers 118.

1. An array substrate including a display area and a non-display area that surrounds the display area, in the non-display area, the array substrate comprising:
first line sections that are portions of a first conductive film and extend in an extending direction along an outer peripheral edge portion of the display area and are disposed with a first space between the first line sections in the extending direction; and
second line sections that are portions of a second conductive film disposed on the first conductive film via a first insulating film,
the second line sections being disposed to overlap end portions of the first line sections, respectively, and disposed with a second space between the second line sections, the second space being smaller than the first space,
the second line sections being connected to the first line sections, respectively via contact portions that are through the first insulating film, and
each of the second line sections having a planar size that is smaller than a planar size of each of the first line sections.

2. The array substrate according to claim 1, wherein the second line sections have end portions that are opposite the second space and have a tapered shape.

3. The array substrate according to claim 1, wherein the end portions of the first line sections have a non-tapered shape.

4. The array substrate according to claim 1 further comprising TFTs arranged in a matrix in the display area, the TFTs including gate electrodes that are portions of the first conductive film and source electrodes that are portions of the second conductive film.

5. A display panel comprising:
the array substrate according to claim 1;
an opposed substrate opposed to the array substrate with having an inner space therebetween; and
a liquid crystal layer disposed in the inner space.

6. A display panel comprising:
the array substrate according to claim 1;
light emission components disposed on the array substrate; and
a sealing layer disposed to cover the light emission components.

7. A method of producing an array substrate including a display area where TFTs are arranged in a matrix and a non-display area surrounding the display area, the method comprising:
forming a first conductive film on an insulating substrate;
etching the first conductive film with patterning via a first photomask and forming first line sections that extend in an extending direction in the non-display area along an outer peripheral edge of the display area and are disposed with a first space in the extending direction;
forming a first insulating film on the first line sections;
etching the first insulating film with patterning via a second photomask and forming contact holes in the first insulating film;
forming a second conductive film on the first insulating film that is patterned and connecting the second conductive film and the first line sections with the second conductive film being disposed in the contact holes; and
etching the second conductive film, which is connected to the first line sections, with patterning via a third photomask that has a light blocking portion having a smaller planar size than the first photomask and forming second line sections so as to overlap end portions of the first line sections and to be arranged with a second space that is smaller than the first space.

8. The method of producing an array substrate according to claim 7, wherein the second line sections have end portions that are opposite the second space and have a tapered shape.

9. The method of producing an array substrate according to claim 7, wherein the end portions of the first line sections have a non-tapered shape.

10. The method of producing an array substrate according to claim 7, wherein
the first conductive film is a gate metal film including portions that are configured as gate electrodes of the TFTs, and
the second conductive film is a source metal film including portions that are configured as source electrodes of the TFTs.
